(19) United States
(12) Patent Application Publication
(10) Pub. No.: US 2026/0112997 A1
(43) Pub. Date: Apr. 23, 2026

(54) OSCILLATOR AND METHOD OF USING AN OSCILLATOR

(71) Applicant: STMICROELECTRONICS INTERNATIONAL N.V., Geneva (CH)

(72) Inventors: Marine BRUN, Aix-en-Provence (FR); Philippe LE FEVRE, Aix-en-Provence (FR); Estelle DANY, Ginasservis (FR)

(21) Appl. No.: 19/353,110

(22) Filed: Oct. 8, 2025

(30) Foreign Application Priority Data
Oct. 21, 2024 (FR) 2411404

(51) Int. Cl. H03B 5/06; H03B 5/12; H03B 5/36

(52) U.S. Cl. CPC H03B 5/06; H03B 5/12; H03B 5/36

(57) ABSTRACT

The present disclosure provides an oscillator. An example oscillator includes: a first connection terminal and a second connection terminal; an amplifier coupled between the first connection terminal and the second connection terminal; and a circuit configured to generate an inductance between the first connection terminal and the second connection terminal. The oscillator being configured to be coupled to a quartz between the first connection terminal and the second connection terminal. The amplifier being configured to drive the quartz.

### CROSS REFERENCE TO RELATED APPLICATION(S)

This application claims the priority benefit of French patent application number FR2411404, filed on Oct. 21, 2024, entitled “Oscillateur et méthode d'utilisation d'un oscillateur”, which is hereby incorporated by reference to the maximum extent allowable by law.

### TECHNICAL FIELD

The present disclosure relates generally to oscillators and methods of using oscillators, and in particular to quartz oscillators.

### BACKGROUND

Some oscillators are configured to be coupled to a quartz. The quartz is configured to receive a signal from the oscillator. The signal has a frequency equal to or close to a characteristic frequency of the quartz, and an energy that is, for example, sufficient for the oscillator to start up. However, the quartz coupled to the oscillator may be one of several different types of quartz, each with different parameters. The oscillator parameters are then adjusted for the type of quartz to which it is connected, so that the oscillator can start up and operate correctly.

There is a need for an oscillator that can be adapted to various types of removable quartz coupled between its terminals and capable, for example, of starting up without user intervention.

### BRIEF SUMMARY

One embodiment provides an oscillator comprising: a first connection terminal and a second connection terminal; an amplifier coupled between the first connection terminal and the second connection terminal; and a circuit configured to generate an inductance between the first connection terminal and the second connection terminal, the oscillator being configured to be coupled to a quartz between the first connection terminal and the second connection terminal, and the amplifier being configured to drive the quartz.

According to one embodiment, the inductance is variable.

According to one embodiment, the oscillator further comprises a measurement circuit configured to measure a capacitance between the first connection terminal and the second connection terminal, the circuit being configured to adjust the inductance value based on the capacitance measurement.

According to one embodiment, the circuit is configured to generate the inductance to be equal to the inverse of the product of the measured capacitance and the oscillator pulsation squared, to within 10%.

According to one embodiment, the oscillator is configured to generate an output signal at a frequency less than 1 MHz.

According to one embodiment, the circuit comprises one or more operational transconductance amplifiers.

According to one embodiment, the transconductance of one or more operational transconductance amplifiers is variable.

Another embodiment provides a method of using an oscillator, comprising: coupling a quartz between a first connection terminal and a second connection terminal of the oscillator; driving the quartz by an amplifier coupled between the first connection terminal and the second connection terminal; and generating an inductance between the first connection terminal and the second connection terminal by a circuit.

According to one embodiment, the inductance is variable.

According to one embodiment, the method further comprises, prior to generating the inductance: measuring a capacitance between the first connection terminal and the second connection terminal, generating the inductance value comprising adjusting the inductance as a function of the measured capacitance value.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates an example of a quartz oscillator;

FIG. 2 is a graphic of the impedance of the oscillator shown in FIG. 1 as a function of its transconductance;

FIG. 3 is a graphic of the impedance of the oscillator shown in FIG. 1 as a function of its transconductance, and as a function of a parameter of a quartz coupled to the oscillator;

FIG. 4 illustrates an example quartz oscillator, according to one embodiment of the present description;

FIG. 5A, FIG. 5B, FIG. 5C, and FIG. 5D illustrate examples of an inductance circuit of a compensation circuit of the quartz oscillator shown in FIG. 4, according to one embodiment of the present description; and

FIG. 6 is a graphic of the impedance of the oscillator shown in FIG. 4 as a function of its transconductance, and as a function of a parameter of a quartz coupled to the oscillator, according to one embodiment of the present description.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the operation of an oscillator is assumed to be known to those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

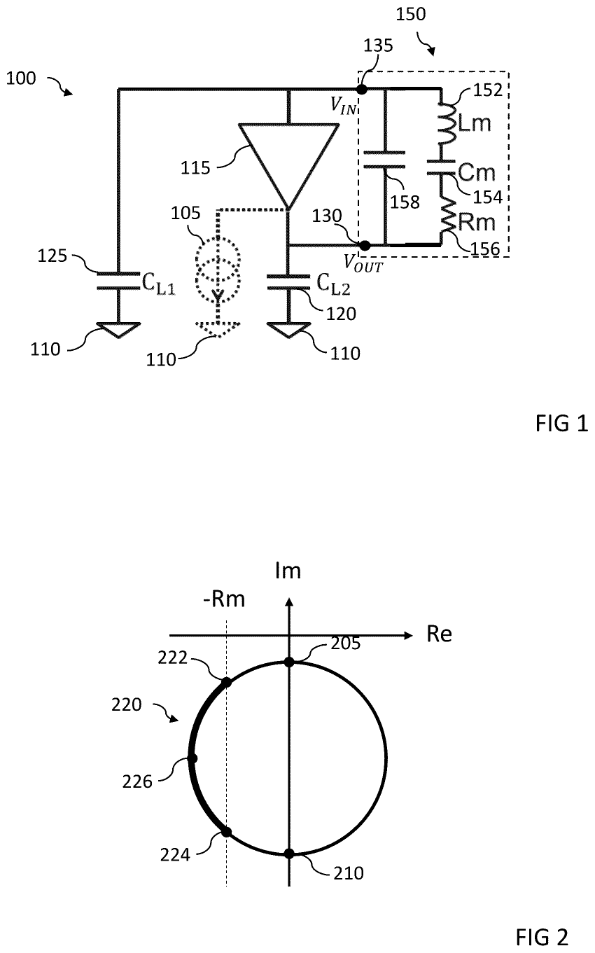

FIG. 1 illustrates an example quartz oscillator 100.

The oscillator 100 is configured to be coupled to a quartz 150, the quartz 150 being removable and external to the oscillator 100. The quartz 150 is configured, for example, to filter a signal, and to transmit signals having a frequency equal or close to a characteristic frequency of the quartz 150.

The oscillator 100 comprises, for example, a current generator 105 configured to generate an AC current I_{AC}. The current generator 105 comprises a first connection terminal, for example coupled to a ground rail 110, and comprises a second connection terminal, for example coupled to a first connection terminal of a current amplifier 115. The current amplifier 115 is configured, for example, to drive the quartz 150. The current amplifier 115 comprises, for example, an internal resistor, not illustrated in FIG. 1. The first connection terminal of the current amplifier 115 is for example further coupled to a first capacitor 120 (“C_{L2}”) having an electrical capacitance C_{L2}. The current amplifier 115 comprises a second connection terminal coupled, for example, to a second capacitor 125 (“C_{L1}”) having an electrical capacitance C_{L1}. The first 120 and second 125 capacitors are, for example, further coupled to the ground rail 110. The first 120 and second 125 capacitors are, for example, external to the oscillator 115, and configured to modulate and adjust the characteristic frequency of the quartz 150.

The oscillator 100 has a first connection terminal 130, coupled to the first connection terminal of the current amplifier 115, and a second connection terminal 135, coupled to the second connection terminal of the current amplifier 115.

Oscillator 100 is configured for coupling to quartz 150, with quartz 150 connected between first 130 and second 135 connection terminals of oscillator 100. The quartz 150 is selected by a user, for example, and the type of quartz, and in particular its parameters, are not set during the design and manufacture of the oscillator 100. Quartz 150 is selected, for example, based on its robustness, power consumption, availability, price, sensitivity to external components and so on.

As illustrated in FIG. 1, the quartz 150 is modeled, for example, by an inductor 1<52, having an inductance value Lm, connected in series with a third capacitor 154, having a capacitance Cm, and connected in series with a resistor 156, having a resistance Rm. Inductor 152, capacitor 154 and resistor 156 are, for example, coupled between the first 130 and second 135 connection terminals of oscillator 100, and coupled in parallel with a fourth capacitor 158, having a capacitance C₀. Capacitor 158 is coupled between the first 130 and second 135 connection terminals of oscillator 100.

The oscillator 100 and quartz 150 are configured to meet certain conditions for the oscillator 100 to start up and operate stably. The oscillator 100 is configured to supply the quartz 150 with enough energy at start-up and during a transient period following start-up. In particular, a transconductance gₘ of the oscillator 100 is configured, for example, to be greater than the conductance of the quartz 150, the transconductance gₘ of the oscillator 100 being defined by:

$$\begin{matrix}[ Math 1 ] & \\ {g}_{m} = \frac{\partial {I}_{OUT}}{\partial {V}_{IN}} {\vert}_{{V}_{OUT} = c} & ( 1 )\end{matrix}$$

where I_{OUT} a current measured at the first connection terminal 130 of the oscillator 100, V_{IN} a voltage applied between the voltage rail 110 and the second connection terminal 135 of oscillator 100, V_{OUT} a voltage applied between the voltage rail 110 and the first connection terminal 130 of oscillator 100, and c a constant.

However, the oscillator 100 is configured so that it does not receive too much power at start-up and its transconductance gₘ is not too high, otherwise an oscillation loop of the oscillator 100 would saturate, and the oscillator 100 would not start.

Note g_{mc} the transconductance of quartz 150. For example, the transconductance g_{mc} is defined by:

$$\begin{matrix}[ Math 2 ] & \\ {g}_{mc} = 4 \cdot Rm \cdot {( 2 π F )}^{2} \cdot {( {C}_{0} + \frac{{C}_{L 1} \cdot {C}_{L 2}}{{C}_{L 1} + {C}_{L 2}} )}^{2} = 4 \cdot Rm \cdot {( 2 π F )}^{2} \cdot {( {C}_{0} + {C}_{L} )}^{2} & ( 2 )\end{matrix}$$

where F is the operating frequency of oscillator 100, and C_{L} a capacitance defined by:

$${C}_{L} = \frac{{C}_{L 1} \cdot {C}_{L 2}}{{C}_{L 1} + {C}_{L 2}} .$$

The operating frequency F is for example between 1 kHz (inclusive) and 50 Mhz (inclusive), and in an example between 30 kHz (inclusive) and 35 kHz (inclusive), and preferably close to 32.768 kHz.

The transconductance g_{mc} of quartz 150, for example, is less than a value g_{mcmax} for the oscillator to start up and operate correctly.

The first 120 and second 125 capacitors are selected, for example, to adjust the frequency of the quartz 150. The value of C_{L} therefore depends on the quartz 150 used.

FIG. 2 is a graphic of an impedance Zc of the oscillator 100 shown in FIG. 1 as a function of its transconductance gₘ, defined by equation (1), represented in a complex plane.

The impedance Zc of oscillator 100 is defined by:

$$\begin{matrix}[ Math 3 ] & \\ Zc = \frac{{V}_{OUT}}{{I}_{OUT}} & ( 3 )\end{matrix}$$

where I_{OUT} the current measured at the first connection terminal 130 of oscillator 100, and V_{OUT} the voltage applied between the voltage rail 110 and the first connection terminal 130 of oscillator 100.

In the complex plane, the impedance Zc of oscillator 100 is, for example, an oval, centered on the imaginary axis (“Im”). The imaginary part of the impedance Zc is maximum, for example, when the transconductance gₘ is equal to 0 (point 205). The imaginary part of the impedance Zc is minimum, for example, when the transconductance gₘ is infinite (point 210). The real part of the impedance Zc is positive, for example, when the transconductance gₘ is less than 0, and the real part of the impedance Zc is negative, for example, when the transconductance gₘ is greater than 0.

Oscillator 100 is for example stable 220, and can for example start if the real part of impedance Zc is less than −Rm, i.e. between points 222 and 224.

Point 224 corresponds, for example, to the impedance Zc when the transconductance gₘ is equal to g_{mcmax}. A point 226 between points 222 and 224 corresponds, for example, to an optimum value gₒₚₜ of the transconductance gₘ.

The optimum value gₒₚₜ of the transconductance gₘ is defined, for example, by:

$$\begin{matrix}[ Math 4 ] & \\ {g}_{opt} = 2 π F \cdot ( {C}_{L 1} + {C}_{L 2} + \frac{{C}_{L 1} {C}_{L 2}}{{C}_{0}} ) . & ( 4 )\end{matrix}$$

When C_{L1} and C_{L2} are equal, gₒₚₜ is defined by:

$$\begin{matrix}[ Math 5 ] & \\ {g}_{opt} = 4 \cdot 2 π F \cdot ( {C}_{L} + \frac{{C}_{{L}^{2}}}{{C}_{0}} ) . & ( 5 )\end{matrix}$$

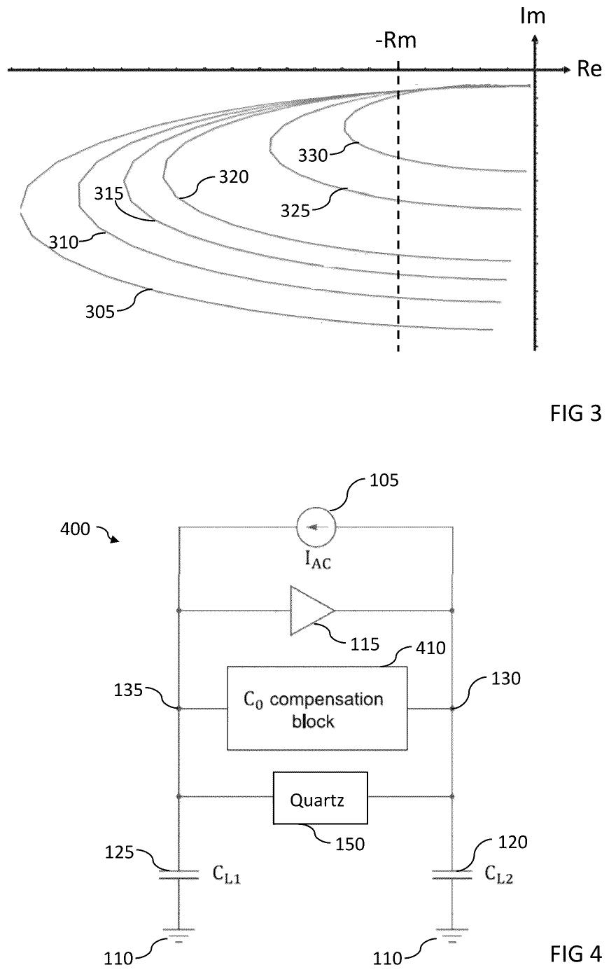

FIG. 3 illustrates a graphic of the impedance Zc of oscillator 100 shown in FIG. 1 as a function of its transconductance gₘ and of a parameter of the quartz 150 coupled to the oscillator.

In particular, each of the curves 305 to 330 in FIG. 3 represents the impedance Zc as a function of gₘ, when the quartz 150, coupled to the oscillator 100, has respectively the fourth capacitor 158 with a capacitance of 0.5 pF, 1 pF, 1.1 pF, 1.2 pF, 2 pF and 3 pF. A transconductance range gₘ compatible with a start-up of oscillator 100, for example corresponding to an impedance Zc having a real part lower than −Rm, varies with the capacitance C₀ generated by quartz 150.

The lower the capacitance C₀ of capacitor 158, the larger the range of transconductance gₘ compatible with starting oscillator 100. It is therefore preferable for the capacitance C₀ to be low.

FIG. 4 illustrates an example of a quartz oscillator 400 according to one embodiment of the present disclosure.

Some of the elements shown in FIG. 4 are similar to the elements shown in FIG. 1. These elements are referred to with the same references, and are not described again in detail.

According to one embodiment, oscillator 400 is a Low Speed External (LSE) oscillator, and oscillates at a frequency of, for example, between 1 kHz (inclusive) and 35 kHz (inclusive), and in one example between 30 kHz (inclusive) and 35 kHz (inclusive), preferably close to 32.768 kHz.

According to other embodiments, the oscillator 400 is a high-speed external oscillator (HSE), and oscillates at a frequency of, for example, between 4 MHz (inclusive) and 50 MHz (inclusive).

The oscillator 400 differs from the oscillator 100 shown in FIG. 1 by the addition of a compensation circuit 410 (“C₀ compensation block”).

The compensation circuit 410 is, for example, coupled between the first 130 and second 135 connection terminals of the oscillator 400. Compensation circuit 410 is, for example, a circuit configured to generate an inductance L between terminals 130 and 135. The inductance L generated by the compensation circuit 410 is in parallel with the quartz 150. In particular, the inductance L generated by the compensation circuit 410 is, for example, in parallel with the fourth capacitor 158 of the quartz 150. The inductance L at least partially compensates for the capacitance C₀.

According to one embodiment, the compensation circuit 410 comprises an inductor coupled between the first 130 and second 135 connection terminals of the oscillator 400.

According to one embodiment, the compensation circuit 410 and quartz 150 together form a quartz-equivalent circuit having a fourth capacitor 158 configured to generate an equivalent capacitance C₀′ less than the capacitance C₀ of the quartz capacitor 158.

According to one embodiment, the compensation circuit 410 is configured so that the inductance L generated has a variable value. For example, circuit 410 comprises a measurement circuit, not illustrated, configured to perform a measurement between the first 130 and second 135 connection terminals of oscillator 400, for example a capacitance measurement. For example, the measurement circuit comprises a capacitor, and is configured to evaluate a capacitance between the first 130 and second 135 connection terminals by measuring the charging or discharging time of the capacitor. For example, circuit 410 further comprises an inductance circuit, not shown in FIG. 4, configured to generate a variable inductance the value of which varies as a function of the value measured between the connection terminals.

According to one embodiment, circuit 410 is configured to generate variable inductance L, L being equal to 1/(Cw²) with C a capacitance measured by the measurement circuit, and w a pulsation, for example equal to 2·π·F with F the operating frequency of oscillator 100.

For example, circuit 410 is configured to generate the variable inductance L, and configured so that the equivalent inductance C₀′ is less than 1 pF, and for example approximately equal to 0.5 pF. For example, circuit 410 is configured so that equivalent inductance C₀′ can be programmed by a user.

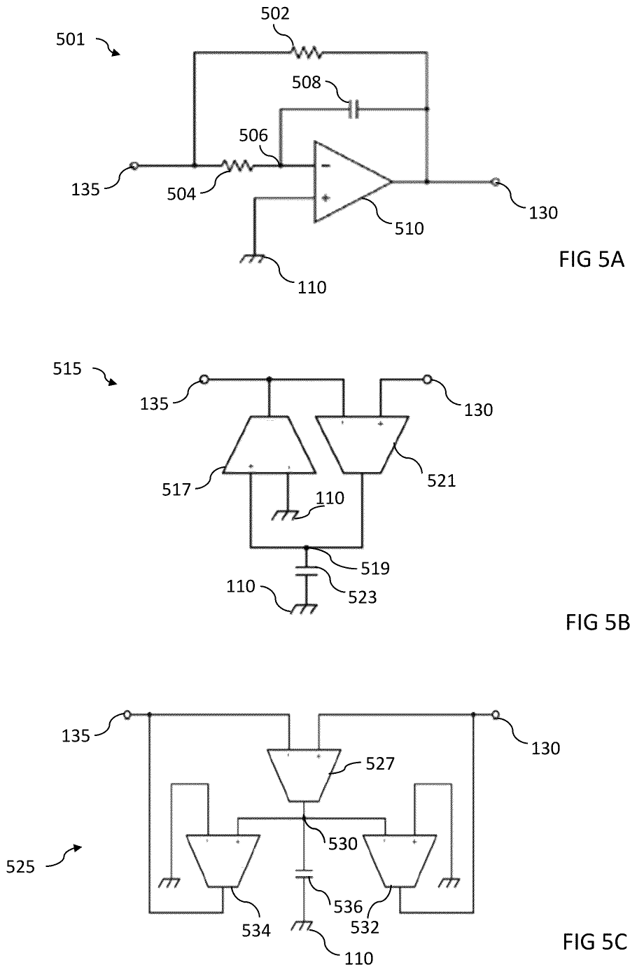

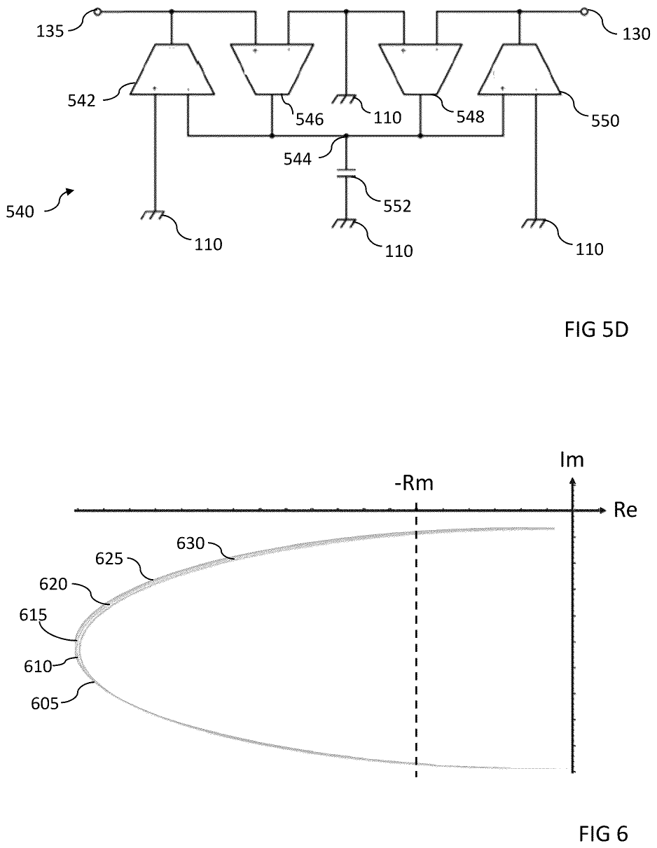

FIGS. 5A to 5D illustrate examples of an inductance circuit implementing the compensation circuit 410 of the oscillator 400 shown in FIG. 4, according to one embodiment of the present description. The inductance circuit is configured, for example, to be equivalent to an inductance having a variable inductance value.

FIG. 5A illustrates a first circuit 501. The circuit 501 comprises, for example, a first resistor 502, having a resistance R1, coupled, preferably connected, between the first 130 and second 135 connection terminals of the oscillator 400 shown in FIG. 4, and comprises, for example, a second resistor 504, having a resistance R2, coupled, preferably connected, between the second connection terminal 135 and an intermediate connection node 506. Circuit 501 further comprises a capacitor 508, having a capacitance C1, coupled, preferably connected, between first connection terminal 130 and intermediate connection node 506, and further comprises an operational amplifier 510 comprising a positive input coupled, preferably connected, to ground rail 110, a negative input coupled, preferably connected, to intermediate connection node 506, and an output coupled, preferably connected, to first connection terminal 130.

For example, circuit 501 is configured to generate an equivalent inductance L defined by: L=C1·R1·R2. At least one of resistor 502 and resistor 504 is, for example, a variable resistor controlled by the measurement circuit, not shown, of compensation circuit 410.

FIG. 5B illustrates a second circuit 515. Circuit 515 comprises, for example, a first operational transconductance amplifier (OTA) 517, configured to generate a transconductance gₘ₁, comprising, for example, a negative input coupled, preferably connected, to ground rail 110, a positive input coupled, preferably connected, to an intermediate connection node 519, and an output coupled, preferably connected, to second connection terminal 135. The circuit 515 further comprises, for example, a second OTA 521, configured to generate a transconductance gₘ₂, comprising for example a negative input coupled, preferably connected, to the second connection terminal 135, a positive input coupled, preferably connected, to the first connection terminal 130, and an output coupled, preferably connected, to the intermediate connection node 519. The circuit 515 further comprises a capacitor 523, having a capacitance C1, coupled, preferably connected, between the intermediate connection node 519 and the ground rail 110.

For example, circuit 515 is configured to generate an equivalent inductance L defined by:

$$L = \frac{C 1}{gm 1 \cdot gm 2} .$$

At least one of OTA 517 and OTA 521 is configured, for example, to generate a variable transconductance controlled by the measurement circuit, not shown, of compensation circuit 410. For example, at least one of the transconductances gₘ₁ and gₘ₂ is controlled by a current. The current is applied to circuit 515, for example between connection terminals 130 and 135, to bias circuit 515.

FIG. 5C illustrates a third circuit 525. The circuit 525 comprises, for example, a first OTA 527, configured to generate a transconductance gₘ₁, comprising, for example, a negative input coupled, preferably connected, to the second connection terminal 135, a positive input coupled, preferably connected, to the first connection terminal 130, and an output coupled, preferably connected, to an intermediate connection node 530. Circuit 525 further comprises, for example, a second OTA 532, configured to generate a transconductance gₘ₂, comprising for example a negative input coupled, preferably connected, to intermediate connection node 530, a positive input coupled, preferably connected, to ground rail 110, and an output coupled, preferably connected, to first connection terminal 130. The circuit 525 further comprises, for example, a third OTA 534, configured to generate the transconductance gₘ₂, comprising for example a positive input coupled, preferably connected, to the intermediate connection node 530, a negative input coupled, preferably connected, to the ground rail 110, and an output coupled, preferably connected, to the second connection terminal 135. The circuit 525 further comprises a capacitor 536, having a capacitance C1, coupled, preferably connected, between the intermediate connection node 530 and the ground rail 110.

For example, circuit 525 is configured to generate an equivalent inductance L defined by:

$$L = \frac{C 1}{gm 1 \cdot gm 2} .$$

At least one of OTA 527, OTA 532, and OTA 534 is configured, for example, to generate a variable transconductance controlled by the measurement circuit, not illustrated, of compensation circuit 410. For example, at least one of the transconductances gₘ₁ and gₘ₂ is controlled by a current. The current is applied to circuit 515, for example between connection terminals 130 and 135, to bias circuit 515.

FIG. 5D illustrates a fourth circuit 540. The circuit 540 comprises, for example, a first OTA 542, configured to generate a transconductance gₘ₁, comprising, for example, a positive input coupled, preferably connected, to the ground rail 110, a negative input coupled, preferably connected, to an intermediate connection node 544, and an output coupled, preferably connected, to the second connection terminal 135. The circuit 540 further comprises, for example, a second OTA 546, configured to generate a transconductance gₘ₂, comprising for example a positive input coupled, preferably connected, to the second connection terminal 135, a negative input coupled, preferably connected, to the ground rail 110 and an output coupled, preferably connected, to the intermediate connection node 544. The circuit 540 further comprises, for example, a third OTA 548, configured to generate the transconductance gₘ₂, comprising, for example, a positive input coupled, preferably connected, to the ground rail 110, a negative input coupled, preferably connected, to the first connection terminal 130 and an output coupled, preferably connected, to the intermediate connection node 544. The circuit 540 further comprises, for example, a fourth OTA 550, configured to generate the transconductance gₘ₁, comprising for example a positive input coupled, preferably connected, to the intermediate connection node 544, a negative input coupled, preferably connected, to the ground rail 110, and an output coupled, preferably connected, to the first connection terminal 130. The circuit 540 further comprises, for example, a capacitor 552, having a capacitance C1, coupled, preferably connected, between the intermediate connection node 544 and the ground rail 110.

For example, circuit 540 is configured to generate an equivalent inductance L defined by:

$$L = \frac{C 1}{gm 1 \cdot gm 2} .$$

At least one of OTA 542, OTA 544, OTA 548, and OTA 550 is for example configured to generate a variable transconductance controlled by the measurement circuit, not illustrated, of compensation circuit 410. For example, at least one of the transconductances gₘ₁ and gₘ₂ is controlled by a current. The current is applied to circuit 515, for example between connection terminals 130 and 135, to bias circuit 515.

FIG. 6 is a graphic of the impedance of the oscillator 400 shown in FIG. 4 as a function of its transconductance, and of the quartz 150 coupled to the oscillator, according to one embodiment of the present description.

In particular, each of the curves 605 to 630 illustrates the impedance Zc as a function of gₘ, when the oscillator 400 is coupled to the quartz 150 having respectively the fourth capacitor 158 configured to generate 0.5 pF, 1 pF, 1.1 pF, 1.2 pF, 2 pF, and 3 pF. In the example shown in FIG. 6, the oscillator 400 is configured so that the compensation circuit 410 generates the variable inductance value L so that the compensation circuit 410 and the quartz 150 are together equivalent to a quartz similar to the quartz 150 having an equivalent capacitance C₀′ approximately equal to 0.5 pF. Each of the curves 605 to 630 varies relatively little with the value of C₀ of the quartz 150. A transconductance range gₘ compatible with starting the oscillator 400, for example corresponding to an impedance Zc having a real part less than −Rm, varies relatively little with the capacitance C₀ generated by the quartz 150.

One advantage of having an oscillator comprising a compensation circuit configured to generate an inductance is to at least partially compensate for the capacitance C₀ of the quartz 150. An equivalent quartz with an equivalent capacitance value C₀′ less than C₀ is obtained. This allows, for example, faster oscillator start-up and/or improved oscillator performance, e.g. reduced oscillator power consumption. Another advantage of having the compensation circuit 410 configured to generate an inductance is to reduce constraints on the transconductance gₘ of the oscillator. In fact, the range of values compatible with oscillator start-up and stable operation is greater for a lower value of C₀′. In practice, a greater variety of quartz types is then compatible with the oscillator, without user intervention or modification of the oscillator parameters. This makes it easier for users to operate the oscillator. It also reduces the number of repetitions of a test to be carried out on the oscillator, which will not, for example, have to be repeated for each of the oscillator modes, which also reduces the risk of error.

One advantage of having an oscillator comprising a compensation circuit configured to generate a variable inductance is to have an oscillator configured to adapt to a relatively large number of quartz types autonomously, without the intervention of a user. For example, the oscillator has a single mode compatible with a wide variety of quartz types. The user doesn't need to understand how the oscillator works to operate it. Oscillator start-up is also faster and the oscillator is, for example, less expensive.

Although various circuits configured to generate an inductance are described in relation to FIGS. 5A to 5D, other circuits are possible and within the scope of those skilled in the art. For example, in addition to the circuit configured to generate an inductance, the compensation circuit could comprise a circuit configured to generate compensation at capacitance C₀.

The oscillator 400, for example, is included in an integrated circuit comprising for example also a microcontroller, such as a radio-frequency microcontroller, or a microprocessor.

For example, the oscillator 400 is included in a real-time counter.

Various embodiments and variants have been described. Those skilled in the art will understand that certain features of these embodiments can be combined and other variants will readily occur to those skilled in the art. In particular, the oscillators 100 and 400 illustrate examples of quartz oscillator circuits, and other variants are available to those skilled in the art.

Finally, the practical implementation of the embodiments and variants described herein is within the capabilities of those skilled in the art based on the functional description provided hereinabove.

1. An oscillator comprising:
a first connection terminal and a second connection terminal;
an amplifier coupled between the first connection terminal and the second connection terminal; and
a circuit configured to generate an inductance between the first connection terminal and the second connection terminal, the oscillator being configured to be coupled to a quartz between the first connection terminal and the second connection terminal, and the amplifier being configured to drive the quartz.

2. The oscillator according to claim 1, wherein the inductance is variable.

3. The oscillator according to claim 2, further comprising a measurement circuit configured to measure a capacitance between the first connection terminal and the second connection terminal, the circuit being configured to adjust an inductance value based on a capacitance measurement.

4. The oscillator according to claim 3, wherein the circuit is configured to generate the inductance to be equal to an inverse of a product of the capacitance measured and an oscillator pulsation squared, to within 10%.

5. The oscillator according to claim 1, configured to generate an output signal at a frequency below 1 MHz.

6. The oscillator according to claim 1, wherein the circuit comprises one or more operational transconductance amplifiers.

7. The oscillator according to claim 6, wherein a transconductance of one or more operational transconductance amplifiers is variable.

8. A method of using an oscillator, comprising:
coupling a quartz between a first connection terminal and a second connection terminal of the oscillator;
driving the quartz by an amplifier coupled between the first connection terminal and the second connection terminal; and
generating an inductance between the first connection terminal and the second connection terminal by a circuit.

9. The method according to claim 8, wherein the inductance is variable.

10. The method according to claim 9, further comprising:
measuring, prior to generating the inductance, a capacitance between the first connection terminal and the second connection terminal, generating an inductance value comprising adjusting the inductance as a function of a measured capacitance value.
